(19) United States
(12) Patent Application Publication
(10) Pub. No.: US 2016/0020320 A1
(43) Pub. Date: Jan. 21, 2016

(54) SEMICONDUCTOR DEVICE

(71) Applicant: KABUSHIKI KAISHA TOSHIBA, Tokyo (JP)

(72) Inventor: Takehito IKIMURA, Yokohama Kanagawa (JP)

(21) Appl. No.: 14/631,220

(22) Filed: Feb. 25, 2015

(30) Foreign Application Priority Data
Jul. 17, 2014 (JP) 2014-147048

(51) Int. Cl. H01L 29/78

(52) U.S. Cl. CPC H01L 29/7818

(57) ABSTRACT

A semiconductor device such as, for example, a diode is described. The semiconductor device includes a first conductivity type substrate layer. A second conductivity-type first semiconductor layer is in a first conductivity-type substrate layer. A first conductivity-type second semiconductor layer is in the first semiconductor layer and separated from the substrate layer. A second conductivity-type third semiconductor layer is in the second semiconductor layer. A first conductivity-type fourth semiconductor layer is in the third semiconductor layer. A first conductivity-type fifth semiconductor layer is in the third semiconductor layer and separated from the fourth semiconductor layer. A second conductivity-type sixth semiconductor layer is in the third semiconductor layer and separated from the fourth semiconductor layer. A first electrode is connected to the fourth semiconductor layer. And a second electrode is connected to the fifth semiconductor layer and the sixth semiconductor layer.

### CROSS-REFERENCE TO RELATED APPLICATION

This application is based upon and claims the benefit of priority from Japanese Patent Application No. 2014-147048, filed Jul. 17, 2014, the entire contents of which are incorporated herein by reference.

### FIELD

Embodiments described herein relate generally to semiconductor devices.

### BACKGROUND

In a region of a semiconductor device in which a transistor and a diode are mounted on a same substrate as an integrated circuit, a leakage current to the substrate can occur in the region in which the diode is formed due to the operation of a parasitic transistor.

### DESCRIPTION OF THE DRAWINGS

FIG. 1 is a schematic sectional view illustrating a semiconductor device according to a first embodiment.

FIGS. 2A and 2B are schematic sectional views illustrating a semiconductor device according to another embodiment.

FIGS. 3A and 3B are schematic sectional views illustrating a semiconductor device according to another embodiment.

FIG. 4 is a schematic sectional view illustrating a semiconductor device according to another embodiment.

### DETAILED DESCRIPTION

An exemplary embodiment provides a semiconductor device that may suppress a leakage current to a substrate.

In general, according to one embodiment, a semiconductor device is provided including a first conductivity-type substrate and a diode provided on the substrate. The diode includes a second conductivity-type first semiconductor layer provided in the substrate, a first conductivity-type second semiconductor layer provided in the first semiconductor layer and separated from the substrate, a second conductivity-type third semiconductor layer provided in the second semiconductor layer, a first conductivity-type fourth semiconductor layer provided in the third semiconductor layer, a first conductivity-type fifth semiconductor layer separated from the fourth semiconductor layer and provided in the third semiconductor layer, a second conductivity-type sixth semiconductor layer separated from the fourth semiconductor layer and provided in the third semiconductor layer, the second conductivity-type sixth semiconductor layer having a second conductivity-type impurity concentration higher than a second conductivity-type impurity concentration of the third semiconductor layer.

Hereinafter, with reference to the drawings, example embodiments will be described. The same elements are identified with the same characters in the various drawings. In the following, a description will be given on the assumption that a first conductivity-type is a p type and a second conductivity-type is an n type, but the embodiments may also be carried out by setting the first conductivity-type as an n type and the second conductivity-type as a p type.

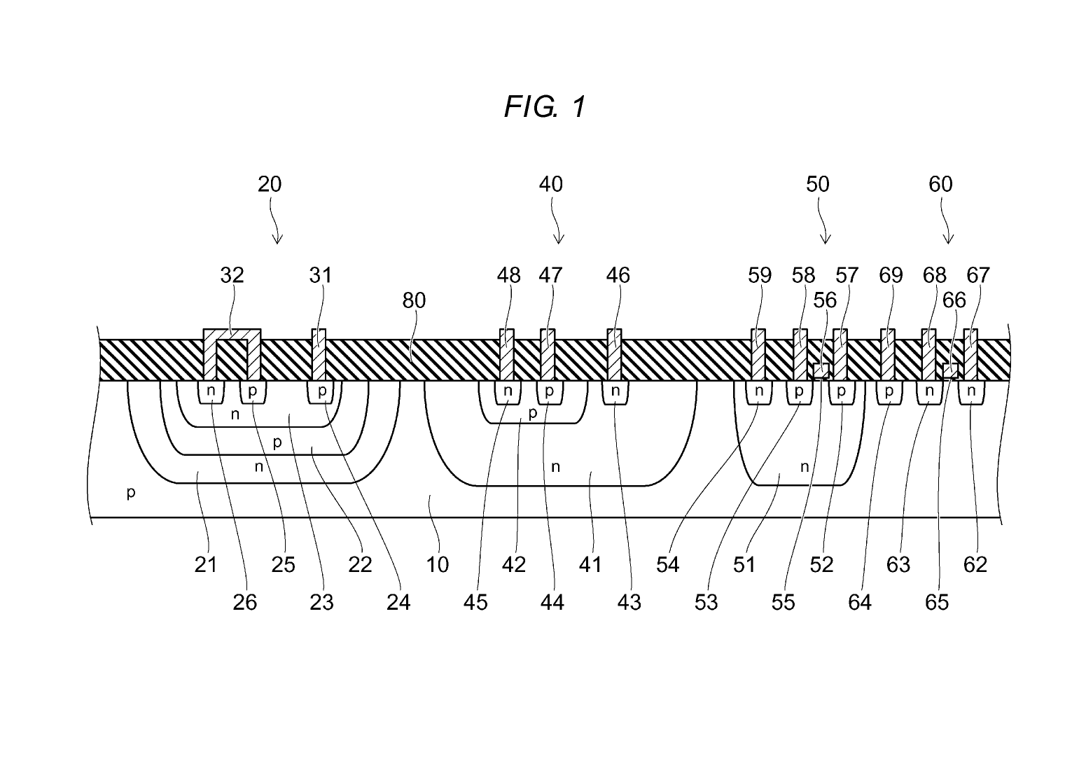

FIG. 1 is a schematic sectional view illustrating a semiconductor device according to a first embodiment.

The semiconductor device according to the first embodiment has a structure in which a diode 20, a bipolar transistor 40, and metal-oxide-semiconductor field effect transistors (MOSFETs) 50 and 60 are mounted on a substrate layer 10 (also referred to as “substrate 10”). Substrate layer 10 may be, for example, a semiconductor wafer or a portion thereof such as a semiconducting layer formed on or in the semiconductor wafer. Substrate layer 10 may also be a semiconductor material disposed on an insulating wafer or the like. The diode 20, the bipolar transistor 40, and the MOSFETs 50 and 60 are provided at a surface of the substrate 10.

Many elements other than the diode 20, the bipolar transistor 40, and the MOSFETs 50 and 60 may be formed on the substrate 10. The diode 20, the bipolar transistor 40, the MOSFETs 50 and 60, and other elements form an integrated circuit.

The substrate 10 is, for example, a p-type silicon substrate. Moreover, each semiconductor layer which will be described below is, in this example, a silicon layer. However, the substrate 10 and the semiconductor layers are not limited only to silicon and may be silicon carbide or gallium nitride, for example.

The bipolar transistor 40 is, for example, an NPN-type bipolar transistor. The bipolar transistor 40 includes an n-type collector layer 41 provided in the substrate 10.

In the collector layer 41, a p-type base layer 42 is provided. In the base layer 42, a p-type base contact layer 44 and an n-type emitter layer 45 are provided in such a way as to be separated from each other. The p-type impurity concentration of the base contact layer 44 is higher than the p-type impurity concentration of the base layer 42.

In the collector layer 41, an n-type collector contact layer 43 is provided separated from the base layer 42. That is, contact layer 43 and base layer 42 are not abutting each other or otherwise directly contacting each other. The n-type impurity concentration of the collector contact layer 43 is higher than the n-type impurity concentration of the collector layer 41.

A surface of each layer of the bipolar transistor 40 is flush with a surface of the substrate 10. On this surface (for example, an upper surface depicted in FIG. 1), an insulating layer 80 is provided.

On the collector contact layer 43, a collector electrode 46 is provided. The collector electrode 46 penetrates the insulating layer 80 and reaches the surface of the collector contact layer 43. The collector contact layer 43 makes ohmic contact with the collector electrode 46 directly or via a metal silicide layer. The collector layer 41 is electrically connected to the collector electrode 46 via the collector contact layer 43.

On the base contact layer 44, a base electrode 47 is provided. The base electrode 47 penetrates the insulating layer 80 and reaches the surface of the base contact layer 44. The base contact layer 44 makes ohmic contact with the base electrode 47 directly or via a metal silicide layer. The base layer 42 is electrically connected to the base electrode 47 via the base contact layer 44.

On the emitter layer 45, an emitter electrode 48 is provided. The emitter electrode 48 penetrates the insulating layer 80 and reaches the surface of the emitter layer 45. The emitter layer 45 makes ohmic contact with the emitter electrode 48 directly or via a metal silicide layer and is electrically connected to the emitter electrode 48.

The MOSFET 50 is a p channel-type MOSFET, and the MOSFET 60 is an n channel-type MOSFET. The MOSFET 50 and the MOSFET 60 form a CMOS circuit.

The MOSFET 50 has an n-type semiconductor layer 51 provided in the substrate 10. In the semiconductor layer 51, a p-type drain layer 52, a p-type source layer 53, and an n-type contact layer 54 are provided in such a way as to be separated from one another. That is, the p-type drain layer 52, the p-type source layer 53, and the n-type contact layer 54 are not abutting each other or otherwise directly contacting each other. As depicted in FIG. 1, portions of semiconductor layer 51 separate the p-type drain layer 52, the p-type source layer 53, and the n-type contact layer 54 from each other. The n-type impurity concentration of the contact layer 54 is higher than the n-type impurity concentration of the semiconductor layer 51. The source layer 53 is provided between the drain layer 52 and the contact layer 54.

A surface region of the semiconductor layer 51 between the drain layer 52 and the source layer 53 becomes a channel region. On the channel region, a gate electrode 56 is disposed such that an insulating film (a gate insulating film) 55 is between the channel region and the gate electrode 56.

A surface of each layer of the MOSFET 50 described above coincides with a surface of the substrate 10. On this surface, the insulating layer 80 is provided.

On the drain layer 52, a drain electrode 57 is provided. The drain electrode 57 penetrates the insulating layer 80 and reaches the surface of the drain layer 52. The drain layer 52 makes ohmic contact with the drain electrode 57 directly or via a metal silicide layer and is electrically connected to the drain electrode 57.

On the source layer 53, a source electrode 58 is provided. The source electrode 58 penetrates the insulating layer 80 and reaches the surface of the source layer 53. The source layer 53 makes ohmic contact with the source electrode 58 directly or via a metal silicide layer and is electrically connected to the source electrode 58.

On the contact layer 54, an electrode 59 is provided. The electrode 59 penetrates the insulating layer 80 and reaches the surface of the contact layer 54. The contact layer 54 makes ohmic contact with the electrode 59 directly or via a metal silicide layer. The electrode 59 is short-circuited (electrically connected) with the source electrode 58, for example.

The MOSFET 60 has an n-type drain layer 62, an n-type source layer 63, and a p-type contact layer 64 which are provided in the substrate 10. The drain layer 62, the source layer 63, and the contact layer 64 are separated from one another on the side of the surface of the substrate 10. That is, the drain layer 62, the source layer 63, and the contact layer 64 do not abut or otherwise directly contact each other along the surface of substrate 10. The p-type impurity concentration of the contact layer 64 is higher than the p-type impurity concentration of the substrate 10. The source layer 63 is provided between the drain layer 62 and the contact layer 64.

A surface region of the substrate 10 between the drain layer 62 and the source layer 63 becomes a channel region. On the channel region, a gate electrode 66 is disposed such that an insulating film (a gate insulating film) 65 is between the channel region and the gate electrode 66.

A surface of each layer of the MOSFET 60 described above is flush with a surface of the substrate 10. On this surface, the insulating layer 80 is provided.

On the drain layer 62, a drain electrode 67 is provided. The drain electrode 67 penetrates the insulating layer 80 and reaches the surface of the drain layer 62. The drain layer 62 makes ohmic contact with the drain electrode 67 directly or via a metal silicide layer and is electrically connected to the drain electrode 67.

On the source layer 63, a source electrode 68 is provided. The source electrode 68 penetrates the insulating layer 80 and reaches the surface of the source layer 63. The source layer 63 makes ohmic contact with the source electrode 68 directly or via a metal silicide layer and is electrically connected to the source electrode 68.

On the contact layer 64, an electrode 69 is provided. The electrode 69 penetrates the insulating layer 80 and reaches the surface of the contact layer 64. The contact layer 64 makes ohmic contact with the electrode 69 directly or via a metal silicide layer. The electrode 69 is short-circuited (electrically connected) with the source electrode 68, for example.

Next, the diode 20 will be described.

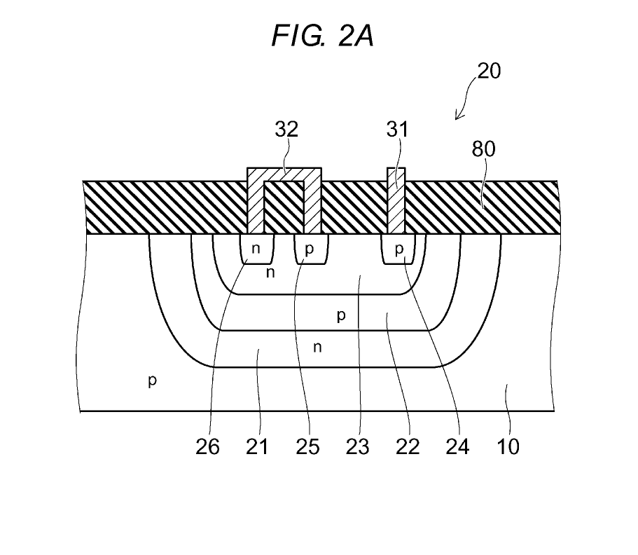

FIG. 2A is a schematic sectional view illustrating the diode 20, according to the first embodiment.

The diode 20 includes an n-type first semiconductor layer 21 provided in the substrate 10. In the first semiconductor layer 21, a p-type second semiconductor layer 22 is provided. In the second semiconductor layer 22, an n-type third semiconductor layer 23 is provided. In the third semiconductor layer 23, a p-type fourth semiconductor layer 24, a p-type fifth semiconductor layer 25, and an n-type sixth semiconductor layer 26 are provided.

The n-type impurity concentration of the sixth semiconductor layer 26 is higher than the n-type impurity concentration of the third semiconductor layer 23. The fourth semiconductor layer 24 is shallower (less distant from the surface of substrate 10 contacting insulation film 80) than the third semiconductor layer 23, and the side and bottom faces of the fourth semiconductor layer 24 form a pn junction with the third semiconductor layer 23.

The fourth semiconductor layer 24, the fifth semiconductor layer 25, and the sixth semiconductor layer 26 are formed of a striped pattern (e.g., when viewed in a top view), for example, and are separated from each other in a direction along the plane at the surface of the substrate 10 contacting the insulating layer 80. Alternatively, the fifth semiconductor layer 25 and the sixth semiconductor layer 26 may contact (abut) each other.

Alternatively, the fifth semiconductor layer 25 may be formed as a different pattern, such as surrounding the sixth semiconductor layer 26 like a ring, and the fourth semiconductor layer 24 may be formed of a similar ring-shaped pattern surrounding the perimeter of the fifth semiconductor layer 25.

The fifth semiconductor layer 25 is provided between the fourth semiconductor layer 24 and the sixth semiconductor layer 26. The fourth semiconductor layer 24 and the fifth semiconductor layer 25 are separated from each other. The fifth semiconductor layer 25 and the sixth semiconductor layer 26 are also separated from each other. Alternatively, the fifth semiconductor layer 25 and the sixth semiconductor layer 26 may be in contact (abutting) with each other.

The depths of the fourth semiconductor layer 24, the fifth semiconductor layer 25, and the sixth semiconductor layer 26 from the surface of the substrate 10 contacting the insulating layer 80 are substantially equal to one another.

A surface of each layer of the diode 20 described above is flush with a surface of the substrate 10. On this surface, the insulating layer 80 is provided.

On the fourth semiconductor layer 24, an anode electrode 31 is provided. The anode electrode 31 penetrates the insulating layer 80 and reaches the surface of the fourth semiconductor layer 24. The fourth semiconductor layer 24 makes ohmic contact with the anode electrode 31 directly or via a metal silicide layer and is electrically connected to the anode electrode 31.

On the fifth semiconductor layer 25, a cathode electrode 32 is provided. The cathode electrode 32 penetrates the insulating layer 80 and reaches the surface of the fifth semiconductor layer 25. The fifth semiconductor layer 25 makes ohmic contact with the cathode electrode 32 directly or via a metal silicide layer and is electrically connected to the cathode electrode 32.

Moreover, the cathode electrode 32 penetrates the insulating layer 80 and also reaches the surface of the sixth semiconductor layer 26. The sixth semiconductor layer 26 makes ohmic contact with the cathode electrode 32 directly or via a metal silicide layer and is electrically connected to the cathode electrode 32.

The potential of the cathode electrode 32 is provided to the third semiconductor layer 23 via the sixth semiconductor layer 26. The second semiconductor layer 22 and the first semiconductor layer 21 are electrically isolated from the potential of the substrate 10, an anode potential and a cathode potential, and are electrically floating.

Alternatively, a potential higher than the anode potential and the cathode potential may be provided to the first semiconductor layer 21.

A ground potential, for example, is provided to the substrate 10. During a forward operation of the diode 20, a positive potential is provided to the anode electrode 31. An intermediate potential which is lower than the potential provided to the anode electrode 31 and is higher than the ground potential is provided to the cathode electrode 32.

When this forward voltage is applied, a positive hole is injected into the third semiconductor layer 23 from the fourth semiconductor layer 24. The positive hole injected into the third semiconductor layer 23 is effectively absorbed by the p-type fifth semiconductor layer 25 which is provided near the fourth semiconductor layer 24 and is connected to the cathode electrode 32. Therefore, the positive hole current easily flows in a surface region of the third semiconductor layer 23 between the fourth semiconductor layer 24 and the fifth semiconductor layer 25 and is less likely to reach the second semiconductor layer 22.

Moreover, a depletion layer is formed between the third semiconductor layer 23 and the substrate 10, and the potential of the first semiconductor layer 21 and the potential of the second semiconductor layer 22 are substantially equal to the potential of the substrate 10. Therefore, even when the positive hole injected into the third semiconductor layer 23 reaches the second semiconductor layer 22, since no electric field exists in that region, little or no positive holes reach the substrate 10 and little or no leakage current flows to the substrate 10 from the anode electrode 31.

Furthermore, during the forward operation, even when the potential of the cathode electrode 32 becomes a negative potential, which is lower than the potential of the substrate 10 (the ground potential), since the positive hole current flowing to the cathode electrode 32 from the substrate 10 is interrupted by the depletion layer described above, it is possible to maintain a breakdown voltage. This allows uses in which the cathode electrode 32 has a negative potential.

Depending on the depth of the third semiconductor layer 23, even in a structure in which the sixth semiconductor layer 26 is located between the fourth semiconductor layer 24 and the fifth semiconductor layer 25, it is possible to make the fifth semiconductor layer 25 effectively absorb the positive hole injected into the third semiconductor layer 23 while suppressing the flow of the positive hole toward the substrate 10.

The semiconductor layers of the above-described diode 20, bipolar transistor 40, and MOSFETs 50 and 60 are formed by using the ion implantation method, for example. The p-type impurities or n-type impurities introduced into an intended region are diffused by heat treatment, whereby the semiconductor layers of the diode 20, the bipolar transistor 40, and the MOSFETs 50 and 60 are formed.

In the example illustrated in FIG. 1, the depths of the n-type semiconductor layers: the first semiconductor layer 21 of the diode 20, the collector layer 41 of the bipolar transistor 40, and the semiconductor layer 51 of the MOSFET 50 are substantially equal to one another, and these n-type semiconductor layers may be formed at the same time in an ion implantation process.

Moreover, the depths of the p-type semiconductor layers: the fourth semiconductor layer 24 and the fifth semiconductor layer 25 of the diode 20, the base layer 44 of the bipolar transistor 40, the drain layer 52 and the source layer 53 of the MOSFET 50, and the contact layer 64 of the MOSFET 60 are substantially equal to one another and may be formed at the same time in an ion implantation process.

Furthermore, the depths of the n-type semiconductor layers: the sixth semiconductor layer 26 of the diode 20, the collector contact layer 43 and the emitter layer 45 of the bipolar transistor 40, the contact layer 54 of the MOSFET 50, and the drain layer 62 and the source layer 63 of the MOSFET 60 are substantially equal to one another and may be formed at the same time in an ion implantation process.

The p-type second semiconductor layer 22 of the diode 20 and the p-type base layer 42 of the bipolar transistor 40 may be made to have substantially the same depth depending on the product design requirements. When the p-type second semiconductor layer 22 of the diode 20 and the p-type base layer 42 of the bipolar transistor 40 have substantially the same depth, it is possible to form the second semiconductor layer 22 and the base layer 42 at the same time in an ion implantation process.

FIG. 2B is a schematic sectional view illustrating a diode according to a second embodiment. The same elements as those of the diode 20 of the embodiment described above, the diode 20 depicted in FIG. 2A, are identified with the same characters and their detailed explanations will be omitted.

The third semiconductor layer 23 is formed by an ion implantation method, for example, and has an impurity concentration distribution which peaks in a depth direction along which the impurities are implanted (e.g., the up-down page direction in FIG. 2B). That is, the impurity concentration distribution is not constant through the third semiconductor layer 23 in the depth direction. In addition, according to the embodiment depicted in FIG. 2B, the third semiconductor layer 23 has an n-type impurity concentration peak in a position (e.g., the position indicated by a broken line in FIG. 2B) deeper than the bottoms of the fourth to sixth semiconductor layers 24, 25, and 26.

An electric current easily flows in a region having a high n-type impurity concentration (e.g., the position indicated by the broken line) and a positive hole current easily flows in a region that is shallower (closer to the surface of substrate 10 on which insulating film 80 is deposed) than the region having the high n-type impurity concentration (e.g., the region at position indicated by the broken line). Therefore, positive holes injected into the third semiconductor layer 23 from the fourth semiconductor layer 24 are prevented by the region having the high n-type impurity concentration (the peak n-type impurity concentration region) from reaching the second semiconductor layer 22 and the positive hole flow is confined to near the surface (e.g., the upper surface in FIG. 2B) of the third semiconductor layer 23. As a result, a leakage current to the substrate 10 may be further suppressed.

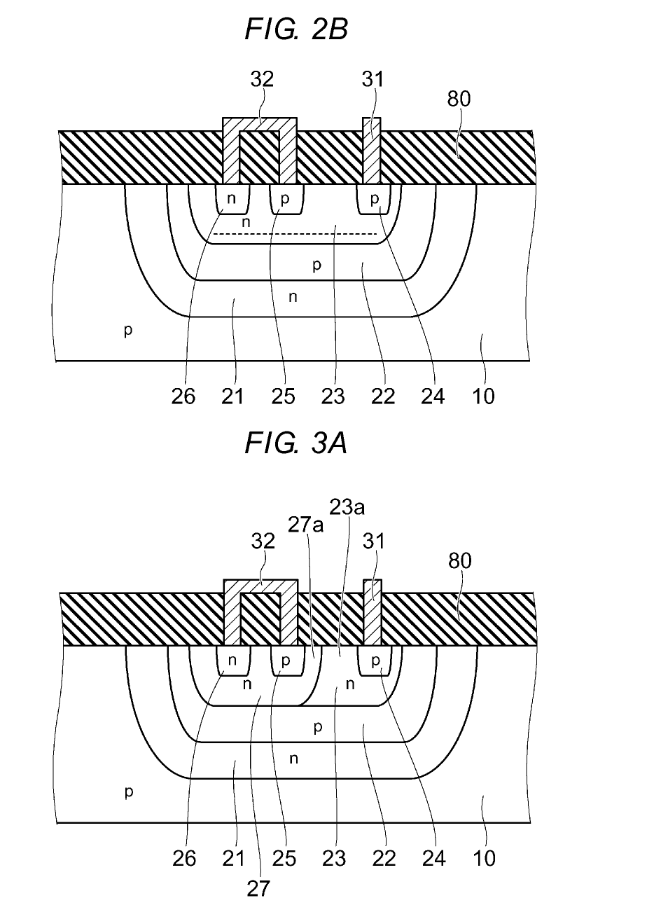

FIG. 3A is a schematic sectional view illustrating a diode according to a third embodiment. The same elements as those of the first and second embodiments described above are identified with the same reference numerals and their detailed explanations may be omitted.

According to the third embodiment depicted in FIG. 3A, in the second semiconductor layer 22, an n-type seventh semiconductor layer 27 is provided so as to abut the third semiconductor layer 23. The fifth semiconductor layer 25 and the sixth semiconductor layer 26 are provided in the seventh semiconductor layer 27.

The n-type impurity concentration of the seventh semiconductor layer 27 is higher than the n-type impurity concentration of the third semiconductor layer 23. Therefore, a region between the fourth semiconductor layer 24 and the fifth semiconductor layer 25 has a first region 23a abutting the fourth semiconductor layer 24 and a second region 27a abutting the fifth semiconductor layer 25, the second region 27a has an n-type impurity concentration that is higher than that of the first region 23a.

The first region 23a is part of the surface region (i.e., the surface contacting insulating layer 80) of the third semiconductor layer 23, and the second region 27a is part of the surface region (i.e., the surface contacting insulating layer 80) of the seventh semiconductor layer 27. That is, first region 23a and second region 27a each include a portion that is at the surface plane of substrate 10.

The n-type impurity concentration of the second region 27a is a concentration in which, when a reverse voltage is applied between the anode electrode 31 and the cathode electrode 32, depletion does not occur in the second region 27a.

During an application of a reverse voltage (a potential higher than a potential applied to the anode electrode 31 is applied to the cathode electrode 32), spreading of the depletion layer from the pn junction between the fourth semiconductor layer 24 and the first region 23a is stopped by the second region 27a having a higher impurity concentration than the first region 23a.

Therefore, it is possible to prevent punch-through in which the depletion layer spreading from the anode side reaches the fifth semiconductor layer 25 at the cathode side and thereby to ensure a high reverse breakdown voltage.

FIG. 3B is a schematic sectional view illustrating a diode according to still another embodiment.

According to the diode depicted in FIG. 3B, in a region above the third semiconductor layer 23 and the seventh semiconductor layer 27, such as a region between the fourth semiconductor layer 24 and the fifth semiconductor layer 25, a control electrode 33 is provided with an insulating film 35 placed between the semiconductor layers 23, 27. In embodiments without the seventh semiconductor layer 27, the control electrode 33 can be disposed above the third semiconductor layer 23.

During the forward operation, the control electrode 33 can be short-circuited with the cathode electrode 32. Alternatively, a negative potential, for example, which is lower than a potential to be provided to the cathode electrode 32 can be provided to the control electrode 33.

During the forward operation, as a result of being attracted by the potential of the control electrode 33, the positive hole is likely to be confined on the surface side of the third semiconductor layer 23 (i.e., the surface contacting the insulating layer 80). Therefore, a leakage current to the substrate 10 may be further suppressed.

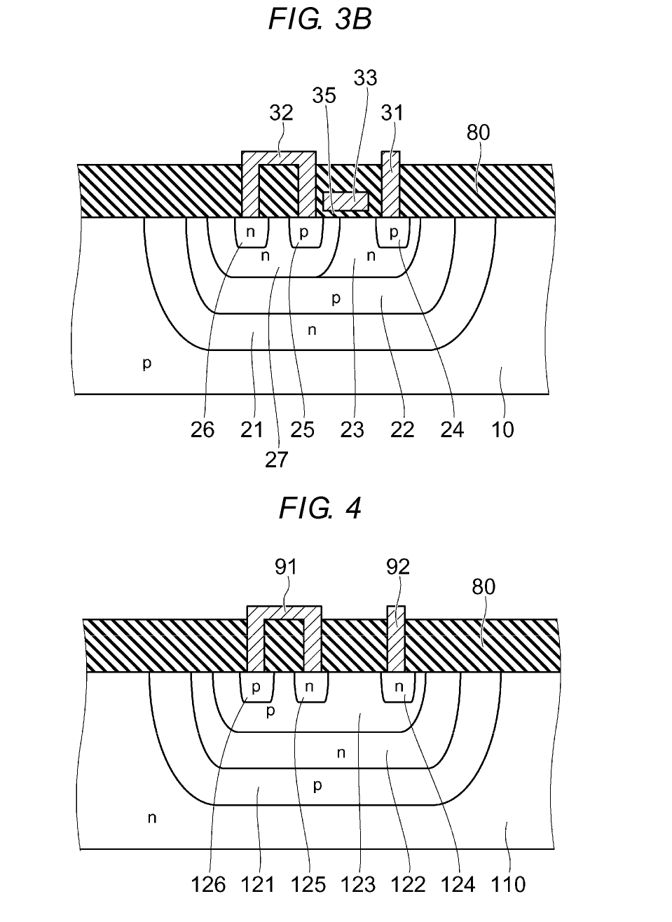

FIG. 4 is a schematic sectional view illustrating a diode according to still another embodiment.

Since the diode depicted in FIG. 4 has a configuration similar to the above-described diode 20 illustrated in FIG. 2A, the configuration in which the conductivity type of each semiconductor layer of the diode 20 illustrated in FIG. 2A is changed to an opposite conductivity type, the explanation thereof will be omitted.

Semiconductor layers 121, 122, 123, 124, 125, and 126 illustrated in FIG. 4 respectively correspond to the semiconductor layers 21, 22, 23, 24, 25, and 26 illustrated in FIG. 2A.

The fourth semiconductor layer 124 is connected to a cathode electrode 92. The fifth semiconductor layer 125 and the sixth semiconductor layer 126 are connected to an anode electrode 91.

Also in the diodes illustrated in FIG. 2B, FIG. 3A, and FIG. 3B, a structure in which the conductivity type is reversed is similarly possible.

The embodiments described above may be appropriately combined and carried out.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate layer of a first conductivity-type;
a first semiconductor layer of a second conductivity-type in the substrate layer;
a second semiconductor layer of the first conductivity-type in the first semiconductor layer and separated from the substrate layer by the first semiconductor layer;
a third semiconductor layer of the second conductivity-type in the second semiconductor layer;
a fourth semiconductor layer of the first conductivity-type in the third semiconductor layer;
a fifth semiconductor layer of the first conductivity-type in the third semiconductor layer and separated from the fourth semiconductor layer;
a sixth semiconductor layer of the second conductivity-type in the third semiconductor layer and separated from the fourth semiconductor layer, the sixth semiconductor layer having a second conductivity-type impurity concentration that is higher than a second conductivity-type impurity concentration of the third semiconductor layer;
a first electrode connected to the fourth semiconductor layer; and
a second electrode connected to the fifth semiconductor layer and the sixth semiconductor layer.

2. The semiconductor device according to claim 1, wherein the first electrode is an anode electrode, and the second electrode is a cathode electrode.

3. The semiconductor device according to claim 1, wherein the first electrode is a cathode electrode, and the second electrode is an anode electrode.

4. The semiconductor device according to claim 1, wherein the fifth semiconductor layer is provided between the fourth semiconductor layer and the sixth semiconductor layer.

5. The semiconductor device according to claim 4, wherein a region of the third semiconductor layer between the fourth semiconductor layer and the fifth semiconductor layer includes a first portion abutting the fourth semiconductor layer and a second portion abutting the fifth semiconductor layer, the second portion having a second conductivity-type impurity concentration higher than a second conductivity-type impurity concentration of the first portion.

6. The semiconductor device according to claim 4, further comprising:
a control electrode and an insulating film, wherein the insulating film is between the third semiconductor layer and the control electrode.

7. The semiconductor device according to claim 6, wherein the control electrode is disposed between the first electrode and the second electrode.

8. The semiconductor device according to claim 1, further comprising:
an insulating layer disposed on a top surface of the third semiconductor layer and a top surface of the fourth semiconductor layer, wherein
the third semiconductor layer has a second conductivity-type dopant concentration level that peaks at a position that is more distant from the insulating layer than a bottom of the fourth semiconductor layer.

9. The semiconductor device according to claim 1, further comprising:
a transistor provided on the substrate layer.

10. A semiconductor device, comprising:
a substrate layer of a first conductivity-type; and
a diode provided on the substrate, the diode comprising:
a first semiconductor layer of a second conductivity-type in the substrate layer;
a second semiconductor layer of the first conductivity-type in the first semiconductor layer and separated from the substrate layer;
a third semiconductor layer of the second conductivity-type in the second semiconductor layer;
a fourth semiconductor layer of the first conductivity-type in the third semiconductor layer; and
a first electrode connected to a surface of the fourth semiconductor layer.

11. The semiconductor device according to claim 10, wherein the diode further comprises:
a fifth semiconductor layer of the first conductivity-type in the third semiconductor layer and separated from the fourth semiconductor layer;
a sixth semiconductor layer of the second conductivity-type in the third semiconductor layer and separated from the fourth semiconductor layer; and
a second electrode connected to a surface of the fifth semiconductor layer and to a surface of the sixth semiconductor layer.

12. The semiconductor device according to claim 11, wherein the fifth semiconductor layer is between the fourth semiconductor layer and the sixth semiconductor layer.

13. The semiconductor device according to claim 11, wherein a region in the third semiconductor layer between the fourth semiconductor layer and the fifth semiconductor layer includes a first portion contacting the fourth semiconductor layer and a second portion contacting the fifth semiconductor layer, the second portion having a second conductivity-type impurity concentration that is higher than a second conductivity-type impurity concentration of the first portion.

14. The semiconductor device according to claim 11, wherein the diode further comprises:
a control electrode; and
an insulating film between the third semiconductor layer and the control electrode.

15. The semiconductor device according to claim 14, wherein the control electrode is disposed between the first electrode and the second electrode.

16. The semiconductor device according to claim 11, wherein the diode further comprises:
an insulating layer disposed on a top surface of the third semiconductor layer and a top surface of the fourth semiconductor layer, wherein
the third semiconductor layer has a second conductivity-type dopant concentration level that peaks at a position more distant from the insulating layer than a bottom of the fourth semiconductor layer.

17. A semiconductor device, comprising:
a substrate layer of a first-conductivity type;
an insulating layer on an upper surface of the substrate layer;
a first semiconductor region of a second-conductivity type between the substrate and the insulating layer;
a second semiconductor region of the first-conductivity type in the first semiconductor region;
a third semiconductor region of the second-conductivity type in the second semiconductor region and separated from the first semiconductor region;
a fourth semiconductor region of the first-conductivity type in the third semiconductor region;
a fifth semiconductor region of the first-conductivity type in the third semiconductor region;
a sixth semiconductor region of the second-conductivity type in the third semiconductor region;
a first electrode electrically contacting the second semiconductor region at the upper surface of the substrate layer; and
a second electrode electrically contacting the third semiconductor region and the fourth semiconductor region at the upper surface of the substrate layer.

18. The semiconductor device according to claim 17, wherein the fourth and fifth semiconductor regions extend from the upper surface of the substrate layer into the third semiconductor region for a same distance in a direction orthogonal to the upper surface of the substrate layer and have a same first-conductivity type dopant concentration level as each other.

19. The semiconductor device according to claim 17, wherein the third semiconductor region has a concentration level of a second-conductivity type dopant that peaks at a distance from the upper surface of the substrate layer that is greater than a distance to which the fourth semiconductor region extends into the third semiconductor region from the upper surface of the substrate layer.

20. The semiconductor device according to claim 17, further comprising:
a control electrode disposed in the insulating layer between the first and second electrodes.
